(19) United States
(12) Patent Application Publication
(10) Pub. No.: US 2021/0096202 A1
(43) Pub. Date: Apr. 1, 2021

(54) DIXON MR IMAGING USING A MULTI-GRADIENT-ECHO SEQUENCE

(71) Applicant: KONINKLIJKE PHILIPS N.V., EINDHOVEN (NL)

(72) Inventors: GABRIELE MARIANNE BECK, VENLO (NL); HOLGER EGGERS, ELLERHOOP (DE)

(21) Appl. No.: 16/971,031

(22) PCT Filed: Feb. 15, 2019
(86) PCT No.: PCT/EP2019/053754

§ 371 Date: Aug. 19, 2020

(30) Foreign Application Priority Data
Feb. 22, 2018 (EP) 18158035.8

(51) Int. Cl. G01R 33/56; G01R 33/44; G01R 33/48; G01R 33/561

(52) U.S. Cl. CPC G01R 33/5608; G01R 33/561; G01R 33/4824; G01R 33/443

(57) ABSTRACT

The invention relates to a method of MR imaging of an object. It is an object of the invention to provide a multi-gradient echo imaging technique with increased acquisition speed and intrinsic suppression of artefacts from Bo inhomogeneities, T₂* decay, chemical shift, motion, and/or flow, in particular in combination with radial or spiral k-space trajectories. The method of the invention comprises the steps of: —subjecting the object (10) to an imaging sequence comprising RF excitation pulses and switched magnetic field gradients, wherein multiple echo signals are generated at different echo times after each RF excitation pulse, —acquiring the echo signal data along radial or spiral k-space trajectories, wherefore the imaging sequence comprises magnetic field gradient blips in the x-/y- and/or z-directions; —separating signal contributions from water and fat to the echo signals and estimating a B₀ map and/or an apparent transverse relaxation time map (T₂* map) using a Dixon algorithm; and —synthesizing an image of a specified contrast from the echo signal data, the Bo map and/or the T₂* map. Moreover, the invention relates to a MR device (1) and to a computer program for a MR device (1).

### FIELD OF THE INVENTION

The invention relates to the field of magnetic resonance (MR) imaging. It concerns a method of MR imaging of an object placed in the examination volume of a MR device. The invention also relates to a MR device and to a computer program to be run on a MR device.

### BACKGROUND OF THE INVENTION

Image-forming MR methods which utilize the interaction between magnetic fields and nuclear spins in order to form two-dimensional or three-dimensional images are widely used nowadays, notably in the field of medical diagnostics, because for the imaging of soft tissue they are superior to other imaging methods in many respects, do not require ionizing radiation and are usually not invasive.

According to the MR method in general, the body of the patient to be examined is arranged in a strong, uniform magnetic field B₀ whose direction at the same time defines an axis (normally the z-axis) of the co-ordinate system to which the measurement is related. The magnetic field B₀ produces different energy levels for the individual nuclear spins in dependence on the magnetic field strength which can be excited (spin resonance) by application of an electromagnetic alternating field (RF field) of defined frequency (so-called Larmor frequency, or MR frequency). From a macroscopic point of view the distribution of the individual nuclear spins produces an overall magnetization which can be deflected out of the state of equilibrium by application of an electromagnetic pulse of appropriate frequency (RF pulse) while the corresponding magnetic field Bi of this RF pulse extends perpendicular to the z-axis, so that the magnetization performs a precessional motion about the z-axis. The precessional motion describes a surface of a cone whose angle of aperture is referred to as flip angle. The magnitude of the flip angle is dependent on the strength and the duration of the applied electromagnetic pulse. In the case of a so-called 90° pulse, the magnetization is deflected from the z axis to the transverse plane (flip angle 90°).

After termination of the RF pulse, the magnetization relaxes back to the original state of equilibrium, in which the magnetization in the z direction is built up again with a first time constant T₁ (spin lattice or longitudinal relaxation time), and the magnetization in the direction perpendicular to the z direction relaxes with a second and shorter time constant T₂ (spin-spin or transverse relaxation time). The transverse magnetization and its variation can be detected by means of receiving RF coils which are arranged and oriented within an examination volume of the MR device in such a manner that the variation of the magnetization is measured in the direction perpendicular to the z-axis. The decay of the transverse magnetization is accompanied by dephasing taking place after RF excitation caused by local magnetic field inhomogeneities facilitating a transition from an ordered state with the same signal phase to a state in which all phase angles are uniformly distributed. The dephasing can be compensated by means of a refocusing RF pulse (for example a 180° pulse). This produces an echo signal (spin echo) in the receiving coils.

In order to realize spatial resolution in the body, time-varying magnetic field gradients extending along the three main axes are superposed on the uniform magnetic field B₀, leading to a linear spatial dependency of the spin resonance frequency. The signal picked up in the receiving coils then contains components of different frequencies which can be associated with different locations in the body. The signal data obtained via the receiving coils correspond to the spatial frequency domain and are called k-space data. The k-space data usually include multiple lines acquired with different phase encoding. Each line is digitized by collecting a number of samples. A set of k-space data is converted to an MR image by means of Fourier transformation.

Altbach et al. (“Radial Fast Spin-Echo Method for T₂-Weighted Imaging and T₂ Mapping of the Liver”, J. Magn. Reson. Imaging, vol. 16, p. 179-189, 2002) describe a multishot radial fast spin echo (RAD-FSE) method developed to improve the quality of abdominal T₂-weighted imaging as well as the characterization of focal liver lesions. A novel radial k-space sampling scheme is used to minimize streaking artifacts due to T₂ variations and motion. Small diffusion gradients are applied to improve flow suppression. A post-processing algorithm is used to generate multiple high-resolution images (at different effective TE values) as well as a T₂ map from the echo signal data. The T₂ map is used to differentiate malignant from benign lesions.

Multi-echo re-combined gradient echo (MERGE) MR imaging is an imaging technique designed to image the cervical spine. In this technique, an imaging sequence, like a fast field echo (FFE) or echo planar imaging (EPI) sequence, is used, which comprises RF excitation pulses and switched magnetic field gradients, wherein multiple echo signals are generated at different echo times (TEs) after each RF excitation pulse. The echo signals can be generated, e.g., by alternating the polarity of the frequency-encoding gradient rapidly. The number of echo signals is limited by apparent transverse relaxation (T₂*) decay. 3-10 echo signals can normally be acquired. Magnitude single echo images are reconstructed from the acquired echo signal data and summed (e.g. by a sums of squares algorithm) to obtain a ‘merged’ multi-echo image showing an increased gray/white matter contrast within the spinal cord and thereby to increase lesion conspicuity in the diagnosis of multiple sclerosis. Corresponding techniques are also known under the acronym MEDIC (‘multi-echo data image combination’).

A problem of the known merged multi gradient echo techniques is that the actual contrast in the combined images is governed by the selected sequence parameters, such as number of echoes, echo spacing, and voxel size, and is thereby limited by various sequence constraints. Moreover, patient motion and flow, as well as system imperfections are known to give rise to false positives in the detection of lesions with these methods.

Furthermore, especially in radial acquisition methods, the readout periods are relatively short compared to EPI or spiral acquisitions. Speed improvements using longer readout periods with a multiple echo readout trajectory are hence highly desirable.

The paper ‘Free breathing volumeric fat/water separation by combining radial sampling, compressed snesing and parallel imaging’ by Th. Benkert et al. in MRM 78 (2017) 565-576 concerns a multi-echo motion-robust stack-of-stars 3D GRE sequence with bipolar read/out. The acquired signals are T₁-weighted. This known method achieves respiration resolved water-fat maps and may reconstruct different respiration states.

### SUMMARY OF THE INVENTION

From the foregoing it is readily appreciated that there is a need for an improved technique that overcomes the above problems. It is one object of the invention to enable merged multi gradient echo MR imaging with optimized contrast.

Moreover—and more generally—it is an object of the invention to provide a multi-echo imaging technique with increased acquisition speed and intrinsic suppression of artefacts from B₀ inhomogeneities, T₂* decay, chemical shift, motion, and/or flow, in particular in combination with radial or spiral acquisitions.

In accordance with the invention, a method of MR imaging of an object placed in the examination volume of a MR device is disclosed. The method comprises the steps of:
subjecting the object to an imaging sequence comprising RF excitation pulses and switched magnetic field gradients, wherein multiple echo signals are generated at different echo times after each RF excitation pulse,
acquiring the echo signal data along radial or spiral k-space trajectories, wherefore the imaging sequence comprises magnetic field gradient blips in the x-/y- and/or z-directions;
separating signal contributions from water and fat to the echo signals and estimating a B₀ map and/or an apparent transverse relaxation time map (T₂* map) using a Dixon algorithm; and
synthesizing an image of a specified contrast from the echo signal data, the B₀ map and/or the T₂* map.

According to the invention, multiple echo signals are acquired at different TEs. The echo signals are acquired along radial or spiral k-space trajectories. Radial or spiral k-space trajectories are preferred over conventional Cartesian k-space trajectories for their intrinsic motion robustness. Using radial or spiral k-space sampling, the center of k-space is oversampled and continuously updated. This redundancy can advantageously be exploited to detect and correct for motion, B₀ and T2* effects.

To obtain a uniform k-space coverage, the rotation angle of the radial or spiral k-space trajectories is preferably incremented by the golden angle, ΔΦ=111.25°, which corresponds to 180° multiplied by the golden ratio. Magnetic field gradient blips (short magnetic field gradient pulses applied between echo signal acquisition intervals after the same RF excitation pulse) in the x-/y- and/or z-directions are used according to the invention to obtain an optimum distribution of the acquired echo signal data in k-space at a fast acquisition speed. For the sake of simplicity, the x-/y-/z-directions refer here to the axes of the measurement coordinate system, i.e. the read-out/phase-encoding/slice-selection directions, which may or may not be aligned with the magnet coordinate system introduced above.

Since the blip encoding time between multiple echo readouts is limited, a tiny golden angle step is preferred for an optimal distribution. Covering at least half of k-space with the number of echoes acquired after the same RF excitation pulse guarantees a uniform distribution over time in 2D imaging. The method can also be adapted to a so-called pseudo golden angle enforcing the golden angle scheme on an equidistant radial grid. The tiny golden angle and pseudo golden angle are herein all regarded as falling under the general term ‘golden angle’. In such golden angle schemes, subsequently sampled radial or spiral k-space trajectories always add complementary information while filling the largest gaps in k-space within the previously sampled set of k-space trajectories.

A Dixon algorithm is used according to the invention to separate contributions from water and fat to the acquired echo signals. In general such a separation is possible because there is a known precessional frequency difference of hydrogen in water and fat. In its simplest form, water and fat images are generated by either addition or subtraction of two echo signals, in which the water and fat signals are ‘in-phase’ and ‘out-of-phase’, respectively. In slightly more complex forms of the Dixon algorithm, a B₀ map and/or a T₂* map is also extracted from the acquired echo signals.

The separation of water and fat and the estimation of a B₀ map and a T₂* map provide flexibility in optimizing the contrast of the synthesized image for particular diagnostic purposes. T₂* results principally from inhomogeneities in the main magnetic field B₀. These inhomogeneities are the result of intrinsic inhomogeneities in the main magnetic field itself and of susceptibility-induced field distortions produced by the tissue. The latter type of B₀ distortions determines the contrast of interest in T₂*-weighted imaging. The influence of the former type of B₀ inhomogeneities on T₂* is considered in the method of the invention to further increase the signal-to-noise ratio and/or enhance the contrast in the synthesized image.

The image is synthesized according to the invention from the acquired echo signal data, wherein a desired T₂* contrast can be chosen and B₀ inhomogeneities and T₂* decay can be compensated for based on the corresponding maps derived from the acquired echo single data.

As a result, the invention enables an ultra-fast 3D radial or spiral (for example stack-of-stars or stack-of-spirals) acquisition with intrinsic B₀ and T₂* mapping and water/fat separation.

The invention is of particular value in combination with the application of contrast agents, as the invention enables the reconstruction (synthesis) of an image with T₁-contrast and of an image with a desired T₂*-contrast (as required for dynamic contrast-enhanced (DCE) MR imaging and dynamic susceptibility contrast (DSC) MR imaging) from the same echo signal data, which can be acquired according to the invention at a very high speed.

Furthermore, it is an insight of the invention that the combined image computed in the known MERGE/MEDIC technique can be considered as a T₂*-weighted image at an effective echo time which is determined by the sequence parameters of the multi echo sequence, namely the number of echoes, the value of the first echo time in the sequence, the echo spacing and also T₂* itself. This insight opens up the possibility to synthesize an image having the desired contrast from the acquired echo signals and the T₂* map without any constraints imposed by the imaging sequence. Concurrently, the derived B₀ map can be used to compensate for B₀ inhomogeneity-induced image artefacts.

In a preferred embodiment of the invention, also a flow map is derived from the acquired echo signal data, wherein the flow map is used in the step of synthesizing the image for compensating for undesirable flow artefacts or to obtain a desired flow contrast.

In three-dimensional acquisitions, the phase encoding of the echo signals can be applied in the x-/y-direction only, the z-direction only, or simultaneously in the x-/y- and z-directions. Hence, in another preferred embodiment of the invention, the phase-encoding of the echo signals is varied in the z-direction while the rotation angle of the radial or spiral k-space trajectories is incremented by the golden angle increment in the kₓ-/k_{y}-directions, wherein a uniform coverage of k-space in the kₓ-/k_{y}-directions is achieved for every single k_{z}-step for a number of adjacent k_{z}-planes. The advantage is an improved motion characteristic.

Furthermore, for speeding up the acquisition, the sampling density in the kₓ-/k_{y}-directions may vary as a function of k_{z} such that a central portion of k-space, which comprises the most relevant information for image contrast, is sampled more densely than the peripheral portions. Hereby, at the peripheral portion of k-space phase encoding in only the z-direction can be performed, while moving towards the central portion of k-space, phase encoding in both x/y and z with a uniform distribution can be used. This variable density approach enables the possibility to extract 3D variable density image navigators from the 3D radial stack of stars data set.

In addition, a good distribution of echo times over k-space can be achieved by shifting x-/y- and z-encoding between successive RF excitations.

In order to facilitate image reconstruction, single echo images may be reconstructed from the echo signal data acquired at the respective echo time.

According to yet another preferred embodiment, a k-space weighted image contrast (KWIC) filter may be used for reconstructing the single echo images (see Song et al., Magn. Reson. Med., 44, 825-832, 2000). Moreover, compressed sensing may be applied for reconstructing the single echo images or within the water/fat separation.

Moreover, a subset of the echo signals may be generated at an ultra-short echo time (UTE) (see Berker et al., J. Nucl. Med. 2012, 53, 796-804) to extend the range of accessible echo time values. Known partial echo techniques may be applied for this purpose as well. Echo shifting may alternatively or additionally be employed to improve the echo time coverage and to optimize the T₂* mapping.

In a further preferred embodiment of the invention, synthesizing the image of a specified contrast involves computing a zero echo time magnitude image and a T₂* map from the acquired echo signal data and applying a weighting to each voxel of the zero echo time magnitude image, which weighting is derived from the T₂* map. The weighting is calculated from the T₂* at the respective voxel location and from the effective echo time which is chosen to obtain the desired contrast. In this way, it can be achieved that the synthesized image resembles a conventional MERGE/MEDIC image (which is generated by magnitude reconstruction of single echo images from the acquired echo signals and combination of the single echo images, e.g., by a sum of squares algorithm) but without the constraints imposed on the contrast by the practically accessible range of sequence parameters.

Preferably, the imaging sequence used by the method of the invention is a fast/turbo field echo (FFE/TFE) or a balanced fast/turbo field echo sequence or an echo planar imaging (EPI) sequence or a spin echo sequence. These are proven techniques usable for fast and effective acquisition of echo signals at different echo times.

In another preferred embodiment of the invention, motion is detected from “intrinsic” data from one or more shots of the imaging sequence and motion-compensation is applied, in the separation of the signal contributions from water and fat, and/or in the synthesis of the image of a specified contrast. Hereby the 3D multi-echo, multi-shot variable density navigator approach allows improved “intrinsic” motion detection and correction possibilities using for example known compressed sensing methods, XD-GRASP or 3D elastic registration combination approaches.

The method of the invention described thus far can be carried out by means of a MR device including at least one main magnet coil for generating a uniform, steady magnetic field B₀ within an examination volume, a number of gradient coils for generating switched magnetic field gradients in different spatial directions within the examination volume, at least one body RF coil for generating RF pulses within the examination volume and/or for receiving MR signals from a body of a patient positioned in the examination volume, a control unit for controlling the temporal succession of RF pulses and switched magnetic field gradients, and a reconstruction unit for reconstructing MR images from the received MR signals. The method of the invention can be implemented by a corresponding programming of the reconstruction unit and/or the control unit of the MR device.

The method of the invention can be advantageously carried out on most MR devices in clinical use at present. To this end it is merely necessary to utilize a computer program by which the MR device is controlled such that it performs the above-explained method steps of the invention. The computer program may be present either on a data carrier or be present in a data network so as to be downloaded for installation in the control unit of the MR device.

### BRIEF DESCRIPTION OF THE DRAWINGS

The enclosed drawings disclose preferred embodiments of the present invention. It should be understood, however, that the drawings are designed for the purpose of illustration only and not as a definition of the limits of the invention. In the drawings:

FIG. 1 shows a MR device for carrying out the method of the invention;

FIG. 2 shows a schematic (simplified) pulse sequence diagram of a multi-gradient echo MR imaging sequence according to the invention;

FIG. 3 illustrates an example of a k-space sampling pattern of the invention;

FIG. 4 shows an example of a merged multi-gradient echo image synthesized according to the invention.

### DETAILED DESCRIPTION OF THE EMBODIMENTS

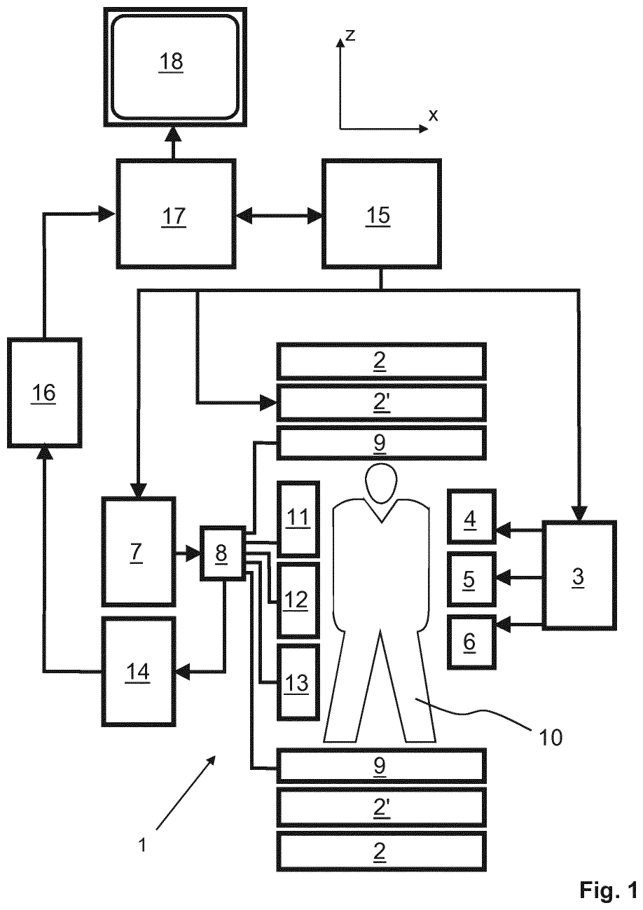

With reference to FIG. 1, a MR device 1 is shown as a block diagram. The device comprises superconducting or resistive main magnet coils 2 such that a substantially uniform, temporally constant main magnetic field B₀ is created along a z-axis through an examination volume. The device further comprises a set of (1^{st}, 2^{nd} and—where applicable—3^{rd} order) shimming coils 2′, wherein the current flow through the individual shimming coils of the set 2′ is controllable for the purpose of minimizing B₀ deviations within the examination volume.

A magnetic resonance generation and manipulation system applies a series of RF pulses and switched magnetic field gradients to invert or excite nuclear magnetic spins, induce magnetic resonance, refocus magnetic resonance, manipulate magnetic resonance, spatially and otherwise encode the magnetic resonance, saturate spins, and the like to perform MR imaging.

More specifically, a gradient amplifier 3 applies current pulses or waveforms to selected ones of whole-body gradient coils 4, 5 and 6 along x, y and z-axes of the examination volume. A digital RF frequency transmitter 7 transmits RF pulses or pulse packets, via a send/receive switch 8, to a body RF coil 9 to transmit RF pulses into the examination volume. A typical MR imaging sequence is composed of a packet of RF pulse segments of short duration which, together with any applied magnetic field gradients, achieve a selected manipulation of nuclear magnetic resonance signals. The RF pulses are used to saturate resonance, excite resonance, invert magnetization, refocus resonance, or manipulate resonance and select a portion of a body 10 positioned in the examination volume. The MR signals are also picked up by the body RF coil 9.

For generation of MR images of limited regions of the body 10 or for scan acceleration by means of parallel imaging, a set of local array RF coils 11, 12, 13 are placed contiguous to the region selected for imaging. The array coils 11, 12, 13 can be used to receive MR signals induced by body coil RF transmissions.

The resultant MR signals are picked up by the body RF coil 9 and/or by the array RF coils 11, 12, 13 and demodulated by a receiver 14 preferably including a preamplifier (not shown). The receiver 14 is connected to the RF coils 9, 11, 12 and 13 via the send/receive switch 8.

A host computer 15 controls the shimming coils 2′ as well as the gradient pulse amplifier 3 and the transmitter 7 to generate any of a plurality of MR imaging sequences, such as echo planar imaging (EPI), echo volume imaging, gradient and spin echo imaging, fast spin echo imaging, and the like. For the selected sequence, the receiver 14 receives a single or a plurality of MR signals in rapid succession following each RF excitation pulse. A data acquisition system 16 performs analog-to-digital conversion of the received signals and converts each MR data sample to a digital format suitable for further processing. In modern MR devices the data acquisition system 16 is a separate computer which is specialized in acquisition of raw image data.

Ultimately, the digital raw image data are reconstructed into an image representation by a reconstruction processor 17 which applies a Fourier transform or other appropriate reconstruction algorithms. The MR image may represent a planar slice through the patient, an array of parallel planar slices, a three-dimensional volume, or the like. The image is then stored in an image memory where it may be accessed for converting slices, projections, or other portions of the image representation into appropriate format for visualization, for example via a video monitor 18 which provides a man-readable display of the resultant MR image.

The host computer 15 is programmed to execute the method of the invention described herein above and in the following.

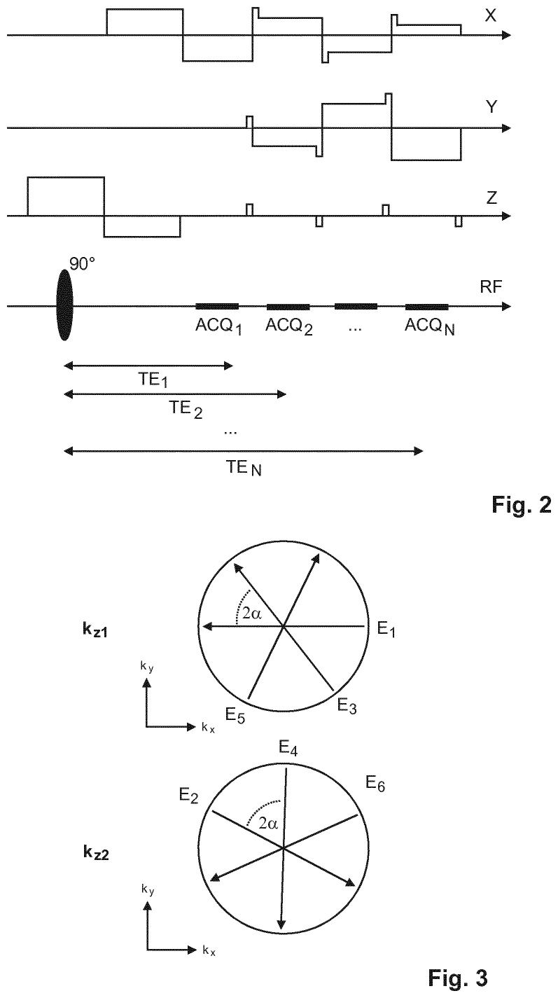

In FIG. 2, a schematic pulse sequence diagram of an imaging sequence according to the invention is depicted. The diagram shows switched magnetic field gradients in the read-out and phase-encoding directions x and y and in the slice-selection direction z. Moreover, the diagram shows an RF excitation pulse as well as the time intervals during which a number of echo signals are acquired, designated by ACQ₁, ACQ₂ and ACQ_{N}. The diagram covers the acquisition of N echo signals. A plurality of sets of N echo signals is acquired by multiple repetitions (shots) of the depicted sequence using different gradient waveforms in the x-/y-directions and/or in the z-direction in order to completely cover the required region of k-space by a radial sampling pattern. The timing and amplitudes of the readout gradients in the x-/y-directions are chosen such that different echo times TE₁, TE₂, . . . , TE_{N} are provided. Short magnetic field gradient blips are applied in addition to the actual read-out magnetic field gradients between the echo signal acquisition time intervals ACQ₁-ACQ_{N} in the x-/y-directions. Blips are also applied in the z-direction for achieving a Cartesian k-space sampling pattern in this direction (stack of stars). A very fast acquisition is achieved in this fashion with an optimum distribution of the acquired echo signal data in k-space.

As further illustrated in FIG. 3, the phase-encoding of the echo signals is varied in the z-direction in a single shot while the rotation angle of the radial k-space trajectories is incremented by the golden angle increment in the kₓ-/k_{y}-directions. In the example of FIG. 3, the magnetic field gradient blips in the z-direction (as shown in FIG. 2) result in k-space being sampled alternatingly in two adjacent k_{z}-planes (designated by k_{z1} and k_{z2}). The sequence of echo signals acquired in a single shot of the imaging sequence is designated as E₁, . . . , E₆. Echo signal E₁ is acquired initially from plane k_{z1}, the rotation angle of the radial k-space profile is then incremented by the tiny golden angle α and the next echo signal E₂ is sampled from plane k_{z2}. The rotation angle is again incremented by alpha, the next echo signal E₃ is acquired again from plane k_{z1}, and so forth. The rotation angle increment between two consecutive k-space profiles acquired from the same plane is thus 2α. A sufficiently high sampling density in the kₓ-k_{y}-plane may thus not be achieved for every single k_{z}-plane, but for a number of adjacent k_{z}-planes. The acquisition speed can be increased significantly in this manner without relevant negative impact on final image quality.

As an intermediate step, single echo images may be reconstructed from the acquired echo signal data: A first single echo image attributed to the first echo time TE₁, a second single echo image attributed to the second echo time TE₂, and so forth. The contributions from water and fat to the respective voxel values are separated by application of a Dixon algorithm of known type on the basis of the different echo times TE₁, . . . , TE_{N}. At the same time, a T₂* map is estimated by including the T₂* decay in the signal model employed in the Dixon algorithm. Alternatively, the separation of water and fat and the estimation of T₂* may be performed directly on the acquired echo signal data without explicitly reconstructing single echo images.

Depending on the type of combination, the images resulting from the known MERGE or MEDIC methods can be described by:

$$\begin{matrix}{S}_{1} = {\sum }_{n = 1}^{N} S {e}^{- {TE}_{n} \text{/} {T}_{2}^{*}} , & ( 1 ) \\ {S}_{2} = {\sum }_{n = 1}^{N} {( S {e}^{- {TE}_{n} \text{/} {T}_{2}^{*}} )}^{2} , & ( 2 ) \\ {S}_{3} = \sqrt{{\sum }_{n = 1}^{N} {( S {e}^{- {TE}_{n} \text{/} {T}_{2}^{*}} )}^{2}} , & ( 3 ) \\ {S}_{4} = \frac{1}{N} \sqrt{{\sum }_{n = 1}^{N} {( S {e}^{- {TE}_{n} \text{/} {T}_{2}^{*}} )}^{2}} , & ( 4 )\end{matrix}$$

wherein N denotes the number of echoes and S denotes a voxel value of the resulting images.

Assuming a constant echo spacing ΔTE, Eq. (1) can be rewritten as:

$$\begin{matrix}{S}_{1} = S {e}^{- {TE}_{1} \text{/} {T}_{2}^{*}} {\sum }_{n = 1}^{N} {e}^{- ( n - 1 ) Δ TE \text{/} {T}_{2}^{*}} , & ( 5 ) \\ {S}_{1} = S {e}^{- {TE}_{1} \text{/} {T}_{2}^{*}} \frac{1 - {e}^{- N Δ TE \text{/} {T}_{2}^{*}}}{1 - {e}^{- Δ TE \text{/} {T}_{2}^{*}}} . & ( 6 )\end{matrix}$$

This allows introducing an effective echo time TE₁ₑ:

S₁=Se^{-TE}^{₁ₑ}^{/T}^{₂}^{*}, (7)

given by:

$$\begin{matrix}{e}^{- {TE}_{1 e} \text{/} {T}_{2}^{*}} = {e}^{- {TE}_{1} \text{/} {T}_{2}^{*}} \frac{1 - {e}^{- N Δ TE \text{/} {T}_{2}^{*}}}{1 - {e}^{- Δ TE \text{/} {T}_{2}^{*}}} , & ( 8 ) \\ {TE}_{1 e} = {TE}_{1} - {T}_{2}^{*} ln ( \frac{1 - {e}^{- N Δ TE \text{/} {T}_{2}^{*}}}{1 - {e}^{- Δ TE \text{/} {T}_{2}^{*}}} ) . & ( 9 )\end{matrix}$$

Similarly, the combined images S₂, S₃, S₄ can be computed using effective echo times given by:

$$\begin{matrix}{TE}_{2 e} = 2 {TE}_{1} - {T}_{2}^{*} ln ( \frac{1 - {e}^{- 2 N Δ TE \text{/} {T}_{2}^{*}}}{1 - {e}^{- 2 Δ TE \text{/} {T}_{2}^{*}}} ) , & ( 10 ) \\ {TE}_{3 e} = {TE}_{1} - \frac{{T}_{2}^{*}}{2} ln ( \frac{1 - {e}^{- 2 N Δ TE \text{/} {T}_{2}^{*}}}{1 - {e}^{- 2 Δ TE \text{/} {T}_{2}^{*}}} ) , & ( 11 ) \\ {TE}_{4 e} = {TE}_{1} + {T}_{2}^{*} ln ( N ) - \frac{{T}_{2}^{*}}{2} ln ( \frac{1 - {e}^{- 2 N Δ TE \text{/} {T}_{2}^{*}}}{1 - {e}^{- 2 Δ TE \text{/} {T}_{2}^{*}}} ) , & ( 12 )\end{matrix}$$

It is thus the insight of the invention that the images resulting from the MERGE or MEDIC methods can be considered as T₂*-weighted images, wherein the effective echo time is indirectly determined by the selected number of echoes, the first echo time, and the echo spacing, but also, and most remarkably, by T₂*.

To overcome the only indirect determination of the effective echo time and any constraints on the imaging sequence, the invention proposes to first estimate a T₂* map from the echo signal data and to then synthesize an image from the estimated zero echo time magnitude image and the T₂* map. The separation of water and fat may be included optionally to provide even more flexibility in optimizing the contrast in the resulting images depending on the particular diagnostic purposes.

To overcome the sensitivity of the known MERGE/MEDIC methods to motion, it is proposed to employ radial or spiral k-space trajectories instead of conventional Cartesian k-space trajectories. Preferably, a projection or interleaf order based on the golden angle is used, and an incremental rotation by a tiny golden angle is applied between successive radial or spiral acquisitions. Additionally, inconsistent data may optionally be rejected and motion may optionally be detected and corrected between the individual acquisitions.

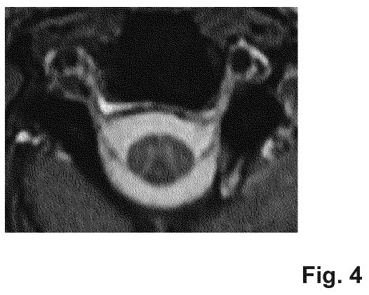

FIG. 4 shows an exemplary image of the spinal cord synthesized by the method of the invention. The image allows excellent differentiation between gray and white matter.

1. A method of magnetic resonance (MR) imaging of an object positioned in an examination volume of a MR device, the method comprising:
subjecting the object to an imaging sequence comprising RF excitation pulses and switched magnetic field gradients, wherein multiple echo signals are generated at different echo times after each RF excitation pulse,
acquiring echo signal data along radial or spiral k-space trajectories, wherein the imaging sequence comprises magnetic field gradient blips in at least on an x-/y- or z-directions, such that different echo times (TE₁, TE₂, . . . , TE_{N}) are provided,
separate from the single echo data signal contributions from water and fat, estimate an apparent transverse relaxation time map (T₂*),
synthesizing T₂*-weighted signals of a specified contrast from the acquired echo signal data, wherein the effective echo time is indirectly determined by the selected number of echoes, the first echo time TE₁, and the echo spacing, and by T₂*, and
reconstructing an image of said specified contrast from the synthesised T₂*-weighted signals, and the apparent transverse relaxation time map (T₂*, map).

2. The method of claim 1, wherein a rotation angle of the radial or spiral k-space trajectories is incremented during acquisition by the golden angle.

3. The method of claim 1, wherein phase-encoding of the echo signals is varied in the z-direction and/or the rotation angle of the radial or spiral k-space trajectories is incremented in the kₓ-/k_{y}-directions.

4. The method of claim 1, wherein the sampling density in the kₓ-/k_{y}-directions varies as a function of k_{z} such that a central portion of k-space is sampled more densely than the peripheral portions.

5. The method of claim 1, wherein one or more shots of the multi-echo acquisition is used to extract an intrinsic image navigation signal which is used for motion correction.

6. (canceled)

7. The method of claim 1, wherein a k-space weighted image contrast (KWIC) filter is used for reconstructing the single echo images.

8. The method of claim 1, wherein compressed sensing is used for reconstructing the single echo images or within the water/fat separation.

9. The method of claim 1, wherein a subset of the echo signals is generated at an ultra-short echo time (UTE).

10. The method of claim 1, wherein synthesizing the image of a specified contrast involves:
computing a zero echo time magnitude image from the acquired echo signal data and
applying a weighting to each voxel of the zero echo time magnitude image, which weighting is derived from the T₂* map.

11. The method of claim 1, wherein the imaging sequence is a field echo sequence or a spin echo sequence.

12. The method of claim 1, wherein motion of the object is detected during the acquisition of the echo signals, wherein a corresponding motion-compensation is applied in the step of reconstructing the single echo images, in the step of separating the signal contributions from water and fat, or in the step of synthesizing the image of a specified contrast.

13. The method of claim 1, wherein the synthesized image resembles an image which is generated by
magnitude reconstruction of single echo images from the acquired echo signal data and
combination of the single echo images by a sum of squares algorithm.

14. The method of claim 1, wherein a flow map is derived from the acquired echo signal data, wherein the flow map is used in the step of synthesizing the image.

15. A magnetic resonance (MR) device including at least one main magnet coil for generating a uniform, steady magnetic field (B₀) within an examination volume, a number of gradient coils for generating switched magnetic field gradients in different spatial directions within the examination volume, at least one RF coil for generating RF pulses within the examination volume and/or for receiving MR signals from an object positioned in the examination volume, a control unit for controlling the temporal succession of RF pulses and switched magnetic field gradients, and a reconstruction unit for reconstructing MR images from the received MR signals, wherein the MR device configured to:
subject the object to an imaging sequence comprising RF excitation pulses and switched magnetic field gradients, wherein multiple echo signals are generated at different echo times after each RF excitation pulse,
acquire the echo signal data along radial or spiral k-space trajectories, wherefore the imaging sequence comprises magnetic field gradient blips in the x-/y- and/or z-directions, such that different echo times (TE₁, TE₂, . . . , TE_{N}) are provided;
separate from the single echo data signal contributions from water and fat and estimate an apparent transverse relaxation time map (T₂* map),
synthesize T₂*-weighted signals of a specified contrast from the acquired echo signal data, wherein the effective echo time is indirectly determined by the selected number of echoes, the first echo time TE₁, and the echo spacing, and by T₂*, and
reconstruct an image of said specified contrast from the synthesised T₂*-weighted signals, and the apparent transverse relaxation time map (T₂* map).

16. A computer program to be run on a magnetic resonance (MR) device, which computer program comprises instructions stored in a non-transistors computer readable medium, such that when the instructions are executed causes the MR device to:
generate an imaging sequence comprising RF excitation pulses and switched magnetic field gradients, wherein multiple echo signals are generated at different echo times after each RF excitation pulse,
acquire the echo signal data along radial or spiral k-space trajectories, wherefore the imaging sequence comprises magnetic field gradient blips in the x-/y- and/or z-directions, such that different echo times (TE₁, TE₂, . . . , TE_{N}) are provided;
separate from the single echo images signal contributions from water and fat, estimating an apparent transverse relaxation time map (T₂* map)
synthesize T₂*-weighted signals of a specified contrast from the acquired echo signal data, wherein the effective echo time is indirectly determined by the selected number of echoes, the first echo time TE₁, and the echo spacing, and by T₂*,
reconstructing an image of said specified contrast from the synthesised T₂*-weighted signals and the apparent transverse relaxation time map (T₂*map).
